(19) United States
(12) Patent Application Publication
(10) Pub. No.: US 2026/0053041 A1
(43) Pub. Date: Feb. 19, 2026

(54) WIRE BOND OBSTRUCTION MITIGATION USING WIRE BOND STUD BUMPS

(71) Applicant: Qorvo US, Inc., Greensboro, NC (US)

(72) Inventor: David B. Crittenden, Celina, TX (US)

(21) Appl. No.: 19/274,929

(22) Filed: Jul. 21, 2025

Related U.S. Application Data
(60) Provisional application No. 63/683,557, filed on Aug. 15, 2024.

(51) Int. Cl. H01L 23/00

(52) U.S. Cl. CPC H01L 24/48; H01L 24/26; H01L 24/29; H01L 24/32; H01L 24/73; H01L 24/83; H01L 24/85; H01L 24/92; H01L 2224/26165; H01L 2224/29111; H01L 2224/29144; H01L 2224/32225; H01L 2224/48155; H01L 2224/48225; H01L 2224/48483; H01L 2224/73265; H01L 2224/8314; H01L 2224/85007; H01L 2224/85051; H01L 2224/92247

(57) ABSTRACT

Aspects of the disclosure advantageously provide one or more methods of improving microelectronic production by mitigating obstructions via strategic placement of wire bond stud bumps. A microelectronic assembly and a method of producing the same are provided. The method includes placing a set of stud bumps on a substrate defining a boundary of a location for placement of a component, wherein the set of stud bumps comprises a first stud bump and a second stud bump, the first stud bump comprising a greater amount of wire bonding material than the second stud bump; placing the component at the location on the substrate via a layer of a binding material; and forming a wire bond between the component and the first stud bump. In one or more embodiments, a microelectronic assembly is produced in accordance with the method described above.

### CROSS-REFERENCE TO RELATED APPLICATIONS

The present application claims the benefit of U.S. Provisional App. No. 63/683,557, entitled “WIRE BOND OBSTRUCTION MITIGATION USING WIRE BOND STUD BUMPS” filed on Aug. 15, 2024, which is incorporated herein by reference in its entirety. The present application is also related to U.S. Provisional App. No. 63/789,172, filed on Apr. 15, 2025, which is incorporated herein by reference in its entirety.

### TECHNICAL FIELD

The present disclosure relates generally to wire bonding, and in particular, relates to wire bond obstruction mitigation using wire bond stud bumps that can be used in production of microelectronic assemblies.

### BACKGROUND

Obstructions—both intentional and unavoidable—are present in various microelectronic assemblies, including, e.g., carrier plate, lead frame, laminate, etc., irrespective of the type of microelectronic assemblies. These obstructions then limit the wire bond interconnection possibilities, which in turn create undesired challenges in microelectronic productions. As a result, design rules and methodologies are developed so as to achieve the desired wire bond interconnect while maintaining a high percentage of assembly yield. The cost of these design rules and methodologies includes a larger assembly footprint, an increase in parasitic aspects of both wire bonds and component placement, and a decrease in the desired performance of the assembly. Thus, there is a need for an improved approach to mitigate such obstructions during microelectronic productions.

### SUMMARY

Embodiments of the present disclosure include methods of wire bonding with obstruction mitigation using wire bond stud bumps. Aspects of the disclosure advantageously provide one or more methods of improving microelectronic production by mitigating obstructions via strategic placement of wire bond stud bumps.

In an exemplary aspect, a method is provided. The method includes placing a set of stud bumps on a substrate defining a boundary of a location for placement of a component, wherein the set of stud bumps comprises a first stud bump and a second stud bump, the first stud bump comprising a greater amount of wire bonding material than the second stud bump; placing the component at the location on the substrate via a layer of a binding material; and forming a wire bond between the component and the first stud bump.

In one or more embodiments, the greater amount of wire bonding material in the first stud bump constitutes a volumetric shape of an extra stud bump disposed atop a stud bump similar in size to the second stud bump. In one or more embodiments, the first stud bump having the greater amount of wire bonding material forms a stud bump with a larger height measured from a surface of the substrate compared to a height of the second stud bump measured from the surface of the substrate.

In one or more embodiments, the forming of the wire bond between the component and the first stud bump is facilitated by a wire bond capillary. In one or more embodiments, the forming of the wire bond between the component and the first stud bump occurs without an obstruction caused by one or more adjacent components interfering with movement of the wire bond capillary during the forming of the wire bond. In one or more embodiments, the one or more adjacent components causing the obstruction comprises a wall or an edge that interferes with a wire bonding process using the wire bond capillary. In one or more embodiments, the binding material may include solder including a gold tin alloy, an epoxy or any pressure sensitive adhesive materials, or any material suitable for eutectic bonding. In one or more embodiments, a microelectronic assembly is produced in accordance with the method described above.

In an exemplary aspect, a method is provided. The method includes placing a set of stud bumps on a substrate defining a boundary of a first location for placement of a first component; placing the first component in the first location on the substrate via a layer of a first binding material; placing a second component at a second location on the substrate via a layer of a second binding material, the second location being adjacent to an edge stud bump of the set of stud bumps and outside of the boundary of the first location; and forming a wire bond between the first component and the second component, wherein the edge stud bump comprises a greater amount wire bonding material than another stud bump of the set of stud bumps.

In one or more embodiments, the greater amount of wire bonding material in the first stud bump constitutes a volumetric shape of an extra stud bump disposed atop a stud bump similar in size to the second stud bump. In one or more embodiments, the first stud bump having the greater amount of wire bonding material forms a stud bump with a larger height measured from a surface of the substrate compared to a height of the second stud bump measured from the surface of the substrate.

In one or more embodiments, the forming of the wire bond between the first component and the second component is facilitated by a wire bond capillary. In one or more embodiments, the forming of the wire bond between the first component and the second component occurs without an obstruction caused by the first component and the second component, or one or more adjacent components, interfering with movement of the wire bond capillary during the forming of the wire bond. In one or more embodiments, the one or more adjacent components causing the obstruction comprises a wall or an edge that interferes with a wire bonding process using the wire bond capillary.

In one or more embodiments, the wire bond is formed by using the edge stud bump having a thickness larger than a thickness of either or both of a combined thickness of the first component and the layer of the first binding material and/or a combined thickness of the second component and the layer of the second binding material. In one or more embodiments, the first and/or second binding material may include solder, such as a gold tin alloy solder, lead solder, a thermoset or thermoplastic material, such as epoxy, or any pressure sensitive adhesive materials. In one or more embodiments, the first and/or second binding material may include any material suitable for eutectic bonding. In one or more embodiments, the first component is a die and the first binding material is a gold tin solder, and the second component is a printed circuit board and the second binding material is epoxy. In one or more embodiments, a microelectronic assembly is produced in accordance with the method described above.

In an exemplary aspect, a microelectronic assembly is provided. The microelectronic assembly includes a substrate having a set of stud bumps disposed thereon, wherein the set of stud bumps define a boundary of a first location; a first component disposed at the first location on the substrate via a layer of a first binding material; a second component disposed at a second location on the substrate via a layer of a second binding material, wherein the second location is adjacent to an edge stud bump of the set of stud bumps and outside of the boundary of the first location; and a wire bond formed between the first component and the second component, wherein the wire bond is formed from the edge stud bump that comprises a greater amount of wire bonding material than another stud bump of the set of stud bumps.

In one or more embodiments, the greater amount of wire bonding material in the first stud bump constitutes a volumetric shape of an extra stud bump disposed atop a stud bump similar in size to the second stud bump. In one or more embodiments, the first stud bump having the greater amount of wire bonding material forms a stud bump with a larger height measured from a surface of the substrate compared to a height of the second stud bump measured from the surface of the substrate.

In one or more embodiments, the wire bond between the first component and the second component is formed by a wire bond capillary. In one or more embodiments, the wire bond between the first component and the second component is formed without an obstruction caused by the first component and the second component, or one or more adjacent components, interfering with movement of the wire bond capillary during the forming of the wire bond. In one or more embodiments, the one or more adjacent components causing the obstruction comprises a wall or an edge that interferes with a wire bonding process using the wire bond capillary.

In one or more embodiments, the wire bond is formed by using the edge stud bump having a thickness larger than a thickness of either or both of a combined thickness of the first component and the layer of the first binding material and/or a combined thickness of the second component and the layer of the second binding material. In one or more embodiments, the first and/or second binding material may include solder, such as a gold tin alloy solder, lead solder, a thermoset or thermoplastic material, such as epoxy, or any pressure sensitive adhesive materials. In one or more embodiments, the first and/or second binding material may include any material suitable for eutectic bonding. In one or more embodiments, the first component is a die and the first binding material is a gold tin solder, and the second component is a printed circuit board and the second binding material is epoxy.

In an exemplary aspect, a microelectronic assembly is provided. The microelectronic assembly includes a substrate having a set of stud bumps disposed thereon, wherein the set of stud bumps comprises a first stud bump and a second stud bump, the first stud bump comprising a greater amount of wire bonding material than the second stud bump; a component disposed at a location on the substrate via a layer of a binding material, wherein the set of stud bumps define a boundary of the location for the component; and a wire bond formed between the component and the first stud bump.

In one or more embodiments, the greater amount of wire bonding material in the first stud bump constitutes a volumetric shape of an extra stud bump disposed atop a stud bump similar in size to the second stud bump. In one or more embodiments, the first stud bump having the greater amount of wire bonding material forms a stud bump with a larger height measured from a surface of the substrate compared to a height of the second stud bump measured from the surface of the substrate.

In one or more embodiments, the wire bond between the component and the first stud bump is formed by a wire bond capillary. In one or more embodiments, wherein the wire bond between the component and the first stud bump is formed without an obstruction caused by one or more adjacent components interfering with movement of the wire bond capillary during the forming of the wire bond. In one or more embodiments, wherein the one or more adjacent components causing the obstruction comprises a wall or an edge that interferes with a wire bonding process using the wire bond capillary. In one or more embodiments, the binding material comprises solder including a gold tin alloy, an epoxy or any pressure sensitive adhesive materials, or any material suitable for eutectic bonding.

Additional aspects, embodiments, implementations, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIGS. 1A, 1B, and 1C illustrate an example process flow for wire bonding, according to aspects of the present disclosure.

FIGS. 1D-1, 1D-2, and 1D-3 illustrate various wire bonds that can be formed using the example process flow illustrated in FIGS. 1A, 1B, and 1C.

FIGS. 2A, 2B, and 2C illustrate an example process flow for wire bonding, according to aspects of the present disclosure.

FIGS. 2D-1, 2D-2, 2D-3, 2D-4, 2D-5, 2D-6, 2D-7, 2D-8, 2D-9, and 2D-10 illustrate various variations of a wire bond that can be formed using the example process flow illustrated in FIGS. 2A, 2B, and 2C.

FIG. 3 illustrates a flowchart for a method for forming a wire bond, according to aspects of the present disclosure.

FIG. 4 illustrates a flowchart for a method for forming a wire bond, according to aspects of the present disclosure.

FIG. 5 illustrates a microelectronic assembly comprising a wire bond, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

In accordance with one or more embodiments, one or more process flows or methods of wire bonding with obstruction mitigation using wire bond stud bumps are provided. Aspects of the disclosure advantageously provide one or more process flows or methods of production of microelectronic assemblies by mitigating obstructions via strategic placement of wire bond stud bumps.

While stacked wire bond stud bumps are commonly used for locating a component, these stud bumps are not used for any additional purposes. In accordance with this disclosure, by employing additional stacked stud bumps in strategic locations, wire bonding sites previously unavailable due to obstructions may now be available for use. As such, strategic placement of stud bumps in unconventional amounts may help reduce or remove obstructions that would normally be in place by effectively lowering the height of the obstruction—or similarly by raising from the surface the end point of the wire bond, although relative amounts of material in the stacked stud bumps may be more or less or equal. In mixed technology assemblies with sequential attachment steps, e.g. gold-tin attached die followed by epoxy attached PCB, necessary sequential steps often reduce the assembly options the further the assembly progresses. This can result from obstructions between materials and minimum dimensions of the assembly tools and equipment. The description below illustrates various solutions that can be implemented in the production of microelectronic assemblies (e.g., microwave integrated assemblies) by mitigating obstructions via strategic placement of wire bond stud bumps as disclosed herein.

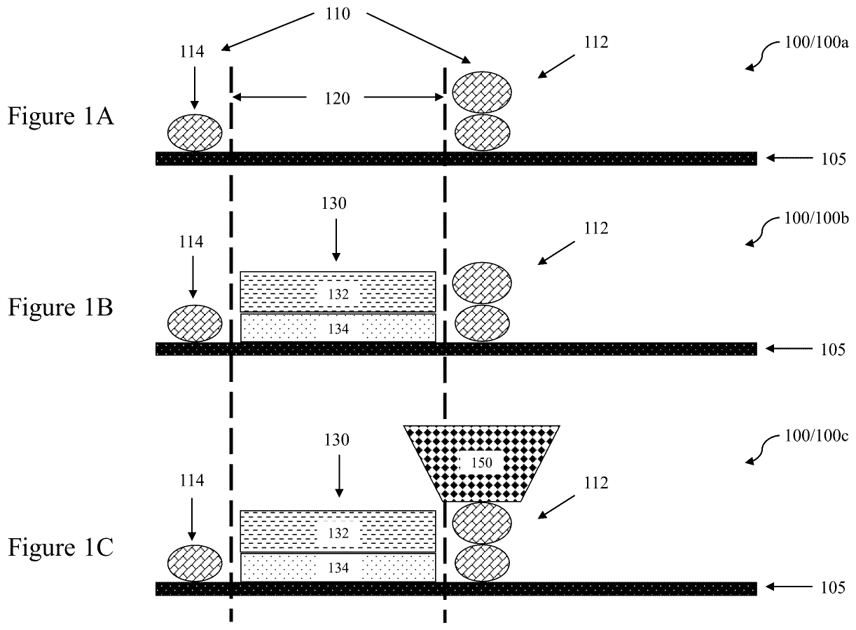

FIGS. 1A, 1B, and 1C illustrate a process flow 100 for wire bonding, according to aspects of the present disclosure. Each of the FIGS. 1A, 1B, and 1C illustrates various stages of the process flow 100, for example, stage 100a in FIG. 1A, stage 100b in FIG. 1B, stage 100c in FIG. 1C. Stage 100d shown in FIGS. 1D-1, 1D-2, and 1D-3 represent different variations (e.g., ball, wedge, ribbon, etc.) of a wire bond 160 that has been formed via the process flow 100, in accordance with various embodiments.

As illustrated in FIG. 1A, the stage 100a of the process flow 100 includes placing a set of stud bumps 110, that includes, for example, a first stud bump 112 and a second stud bump 114, which define a boundary 120 on a substrate 105 for a location 130 for placement of a component 132. Although the boundary 120 is shown with two vertical dash-lines defining its outer-edges (e.g., left and right boundaries) in two dimensions as shown in FIG. 1A, the boundary 120 can nevertheless encompass a boundary in three dimensions in any shape or areal form, including but not limited to, for example, rectangular, triangle, oval, or any irregular boundaries, as desired.

As further illustrated in FIG. 1A, the first stud bump 112 can have a greater amount of wire bonding material than the second stud bump 114. In one or more embodiments, the first stud bump 112 can have enough wire bonding material such that the first stud bump 112 has a larger height measured from a surface of the substrate 105 compared to a height of the second stud bump 114 measured from the surface of the substrate 105. In one or more embodiments, the greater amount of wire bonding material in the first stud bump 112 may constitute a volumetric shape of an extra stud bump disposed atop a stud bump similar in size to the second stud bump 114. In other words, the first stud bump 112 may comprise stacked stud bumps (i.e., multiple stud bumps stacked on top of one another), as shown as shown in FIGS. 1A, 1B, 1C, 1D-1, 1D-2, and 1D-3.

In one or more embodiments, the first stud bump 112 can have at least about 10%, at least about 20%, at least about 30%, at least about 40%, at least about 50%, at least about 60%, at least about 70%, at least about 80%, at least about 90%, at least about 100%, at least about 120%, at least about 140%, at least about 160%, at least about 180%, at least about 200%, at least about 250%, at least about 300%, at least about 350%, at least about 400%, at least about 450%, or at least about 500% more wire bonding material than the second stud bump 114. In one or more embodiments, the second stud bump 114 includes a single stud bump and the first stud bump 112 can have two, three, four, or five stud bumps. In one or more embodiments, the first stud bump 112 can have two, three, four, or five times as many stud bumps as the second stud bump 114.

As further illustrated in FIG. 1B, the stage 100b of the process flow 100 includes placing the component 132 at the location 130 defined by the boundary 120 on the substrate 105 via a layer of a binding material 134, in accordance with one or more embodiments. In one or more embodiments, the component 132 may include a die, a printed circuit board, an integrated circuit, a microelectronic assembly, etc. In one or more embodiments, the binding material 134 may include solder, such as a gold tin alloy solder, lead solder, a thermoset or thermoplastic material, such as epoxy, or any pressure sensitive adhesive materials. In one or more embodiments, the binding material 134 may include any material suitable for eutectic bonding.

As illustrated in FIG. 1C, the stage 100c of the process flow 100 includes forming a wire bond (not shown) between the component 132 and the first stud bump 112. FIGS. 1D-1, 1D-2, and 1D-3 illustrate various variations of the wire bond 160 that can be formed using the example process flow illustrated in FIGS. 1A, 1B, and 1C. In one or more embodiments, the wire bond 160 may be formed using a wire bond capillary 150. In other words, the forming of the wire bond 160 between the component 132 and the first stud bump 112 can be facilitated by the wire bond capillary 150.

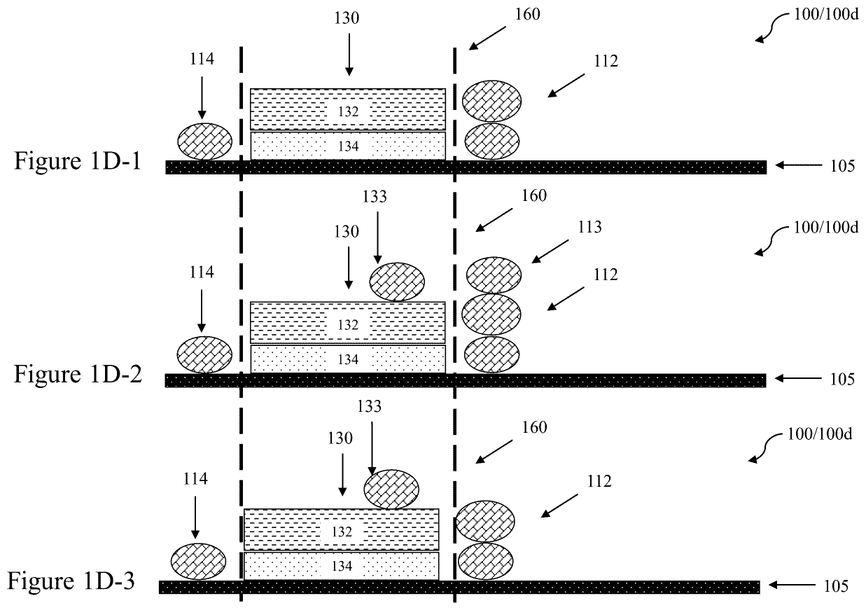

As shown in FIG. 1D-1, the wire bond 160 may be formed between the component 132 and the first stud bump 112. The wire bond 160 may be formed between the component 132 and the first stud bump 112 via a third stud bump 113 and a fourth stud bump 133, as shown in FIG. 1D-2. In one embodiment, the wire bond 160 may be formed between the component 132 and the first stud bump 112 via the fourth stud bump 133, as shown in FIG. 1D-3.

In one or more embodiments, the forming of the wire bond 160 between the component 132 and the first stud bump 112 occurs without an obstruction caused by one or more adjacent components (not shown) interfering with movement of the wire bond capillary 150 during the forming of the wire bond. In one or more embodiments, the one or more adjacent components causing the obstruction comprises a wall or an edge (not shown) that interferes with a wire bonding process using the wire bond capillary 150. In such embodiments, the first stud bump 112 has enough wire bonding material such that the first stud bump 112 has a larger height measured from the surface of the substrate 105 compared to a height of the component 132 measured from the surface of the substrate 105. In other words, the first stud bump 112 has enough wire bonding material or taller enough such that the wire bond capillary 150 can make contact with the first stud bump 112 for forming the wire bond. The wire bond may not be formed if the first stud bump 112 has a height that is not higher than the height of the component 132 measured from the surface of the substrate 105, where the component 132 may interfere or obstruct the wire bond capillary 150 from making physical contact with the first stud bump 112. Similarly, the second stud bump 114 shall have a height not to exceed the height of the component 132 (with or without the binding material 134) measured from the surface of the substrate 105; otherwise, an inadvertent wire bond may form from the wire bond capillary 150 contacting the second stud bump 114.

In one or more embodiments, a microelectronic assembly may be produced in accordance with the process flow 100 described above.

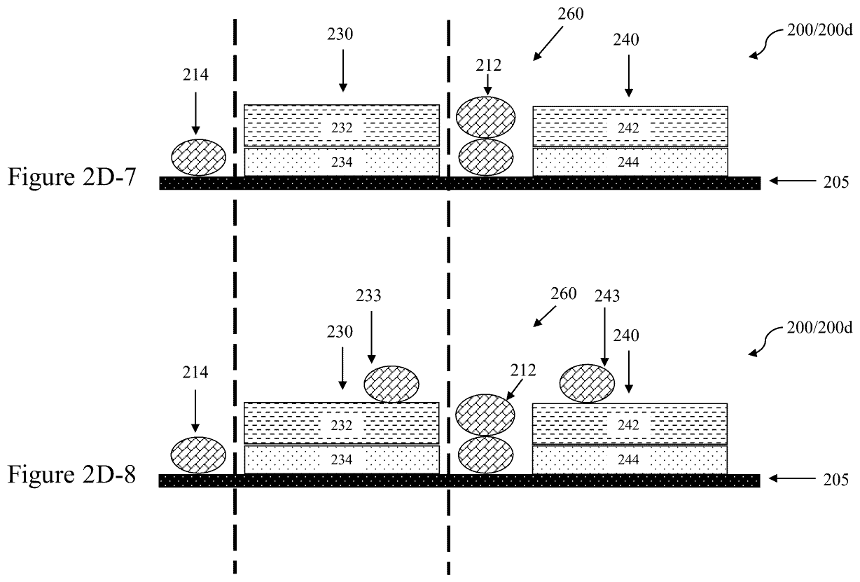

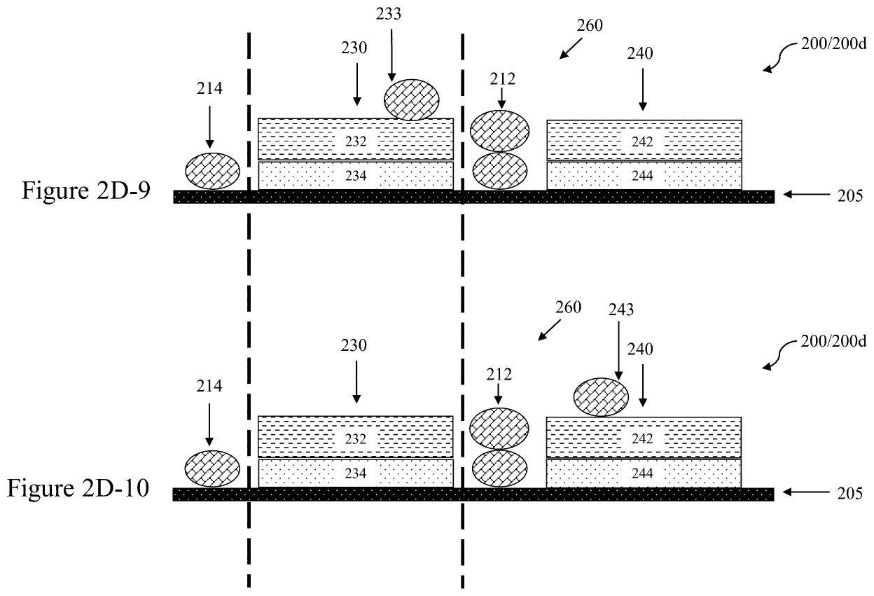

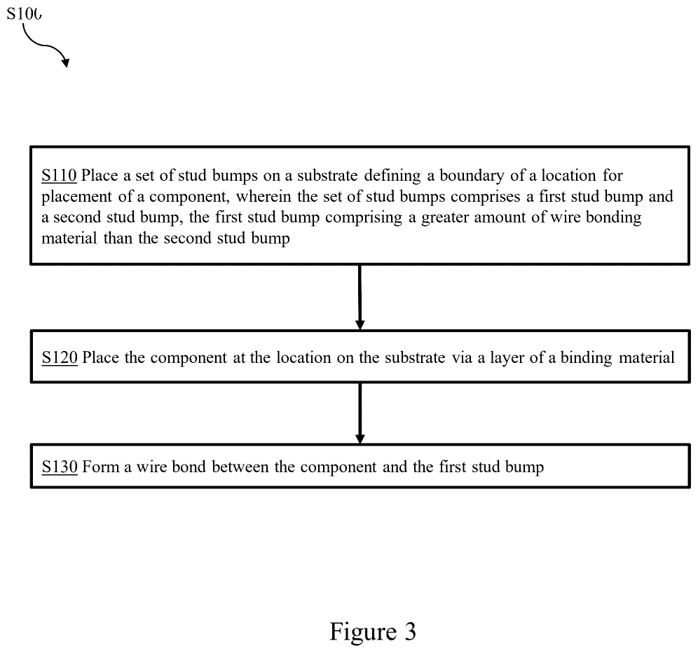

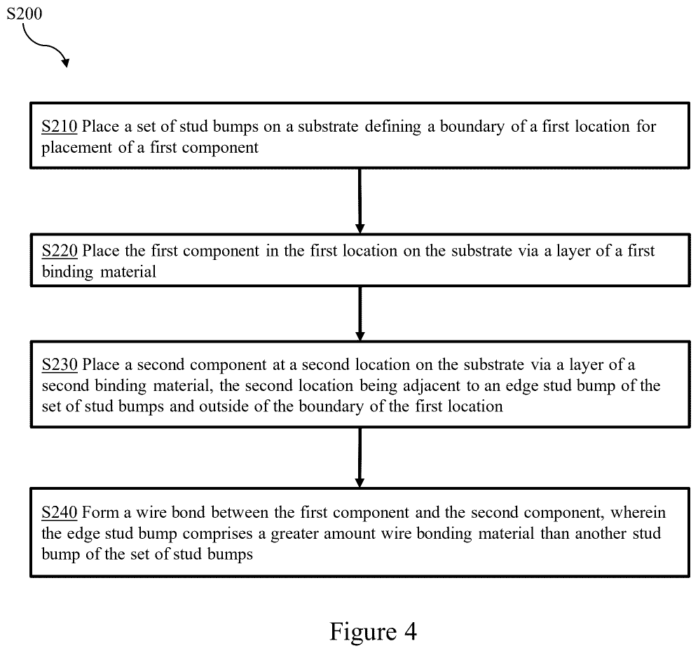

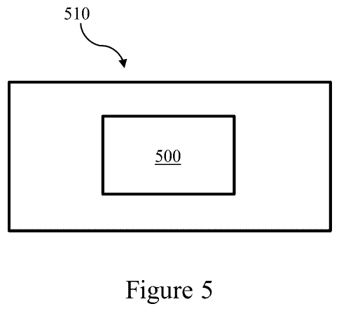

FIGS. 2A, 2B, and 2C illustrate a process flow 200 for wire bonding, according to aspects of the present disclosure. Each of the FIGS. 2A, 2B, and 2C illustrates various stages of the process flow 200, for example, stage 200a in FIG. 2A, stage 200b in FIG. 2B, and stage 200c in FIG. 2C. Stage 200d shown in FIGS. 2D-1, 2D-2, 2D-3, 2D-4, 2D-5, 2D-6, 2D-7, 2D-8, 2D-9, and 2D-10 illustrate various variations (e.g., ball, wedge, ribbon, etc.) of a wire bond 260 that can be formed via the process flow 200, in accordance with various embodiments.

As illustrated in FIG. 2A, the stage 200a of the process flow 200 includes placing a set of stud bumps 210, that includes, for example, a first stud bump 212 and a second stud bump 214, on a substrate 205, which define a boundary 220 for a first location 230 for placement of a first component 232. Although the boundary 220 is shown with two vertical dash-lines defining its outer-edges (e.g., left and right boundaries) in two dimensions as shown in FIG. 2A, the boundary 220 can nevertheless encompass a boundary in three dimensions in any shape or areal form, including but not limited to, for example, rectangular, triangle, oval, or any irregular boundaries, as desired.

As further illustrated in FIG. 2A, the first stud bump 212 can have a greater amount of wire bonding material than the second stud bump 214. In one or more embodiments, the first stud bump 212 can have enough wire bonding material such that the first stud bump 212 has a larger height measured from a surface of the substrate 205 compared to a height of the second stud bump 214 measured from the surface of the substrate 205. In one or more embodiments, the greater amount of wire bonding material in the first stud bump 212 may constitute a volumetric shape of an extra stud bump disposed atop a stud bump similar in size to the second stud bump 214. In other words, the first stud bump 212 may comprise stacked stud bumps (i.e., multiple stud bumps stacked on top of one another), as shown in FIGS. 2A, 2B, 2C, 2D-1, 2D-2, 2D-3, 2D-4, 2D-5, 2D-6, 2D-7, 2D-8, 2D-9, and 2D-10.

In one or more embodiments, the first stud bump 212 can have at least about 10%, at least about 20%, at least about 30%, at least about 40%, at least about 50%, at least about 60%, at least about 70%, at least about 80%, at least about 90%, at least about 100%, at least about 120%, at least about 140%, at least about 160%, at least about 180%, at least about 200%, at least about 250%, at least about 300%, at least about 350%, at least about 400%, at least about 450%, or at least about 500% more wire bonding material than the second stud bump 214. In one or more embodiments, the second stud bump 214 includes a single stud bump and the first stud bump 212 can have two, three, four, or five stud bumps. In one or more embodiments, the first stud bump 212 can have two, three, four, or five times as many stud bumps as the second stud bump 214.

As illustrated in FIG. 2B, the stage 200b of the process flow 200 includes placing the first component 232 at the first location 230 on the substrate 205 via a layer of a first binding material 234, in accordance with one or more embodiments. In one or more embodiments, the first component 232 may include a die, a printed circuit board, an integrated circuit, a microelectronic assembly, etc. In one or more embodiments, the first binding material 234 may include solder, such as a gold tin alloy solder, lead solder, a thermoset or thermoplastic material, such as epoxy, or any pressure sensitive adhesive materials. In one or more embodiments, the first binding material 234 may include any material suitable for eutectic bonding.

The stage 200b of the process flow 200 may also include placing a second component 242 at a second location 240 on the substrate 205 via a layer of a second binding material 244, as illustrated in FIG. 2A. In one or more embodiments, the second component 242 that is placed at the second location 240 may include a die, a printed circuit board, an integrated circuit, a microelectronic assembly, etc. In one or more embodiments, the second binding material 244 may include solder, including for example, a gold tin alloy solder, lead solder, a thermoset material, a thermoplastic material, such as epoxy, or any pressure sensitive adhesive materials. In one or more embodiments, the second binding material 244 may include any material suitable for eutectic bonding.

As shown in FIG. 2B, the second location 240 and the first location 230 are separated by the first stud bump 212. In other words, the second location 240 is adjacent to an edge stud bump, which, as shown in FIG. 2A, is the first stud bump 212 (also referred to herein as the edge stud bump 212) of the set of stud bumps 210. In another word, the second location 240 is outside of the boundary 220 of the first location 230.

As further illustrated in FIG. 2C, the stage 200c of the process flow 200 includes forming a wire bond (not shown) between the first component 232 and the second component 242. In one or more embodiments, the wire bond may be formed using a wire bond capillary 250, as depicted in FIG. 2C. In other words, the forming of the wire bond between the first component 232 and the second component 242 can be facilitated by the wire bond capillary 250. In one or more embodiments, the wire bond is formed by using first/edge stud bump 212 having a thickness larger than a thickness of either or both of a combined thickness of the first component 232 and the layer of the first binding material 234 and/or a combined thickness of the second component 242 and the layer of the second binding material 244.

FIGS. 2D-1, 2D-2, 2D-3, 2D-4, 2D-5, 2D-6, 2D-7, 2D-8, 2D-9, and 2D-10 illustrate various variations of the wire bond 160 that can be formed via the process flow 200, in accordance with various embodiments. In one or more embodiments, the wire bond 260 may be formed using a wire bond capillary 250. In other words, the forming of the wire bond 260 between the first component 232 and the second component 242 and/or stud bumps 212, 213, 233, 243, etc., can be facilitated by the wire bond capillary 250, as illustrated in FIGS. 2D-1, 2D-2, 2D-3, 2D-4, 2D-5, 2D-6, 2D-7, 2D-8, 2D-9, and 2D-10.

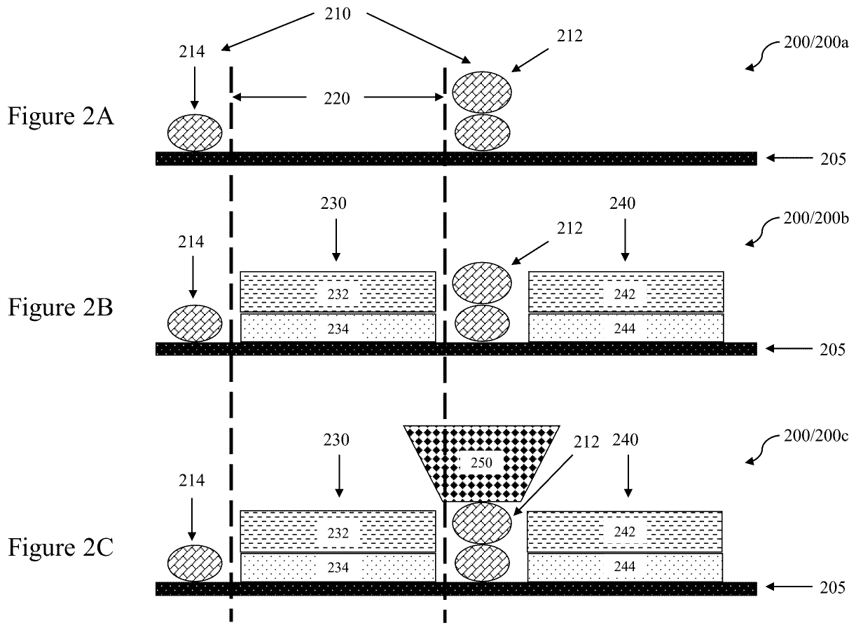

As shown in FIG. 2D-1, the wire bond 260 may be formed between the first component 232 and the first stud bump 212. The wire bond 260 may be formed between the first component 232 and the first stud bump 212 via a third stud bump 213 and a fourth stud bump 233, as shown in FIG. 2D-2. In one embodiment, the wire bond 260 may be formed between the first component 232 and the first stud bump 212 via the fourth stud bump 233, as shown in FIG. 2D-3. As further illustrated in FIG. 2D-4, the wire bond 260 may be formed between the second component 242 and the first stud bump 212. As shown in FIG. 2D-5, the wire bond 260 may be formed between the second component 242 and the first stud bump 212 via the third stud bump 213 and a fifth stud bump 243. In some embodiments, the wire bond 260 may be formed between the second component 242 and the first stud bump 212 via the fifth stud bump 243, as shown in FIG. 2D-6.

As further illustrated in FIG. 2D-7, the wire bond 260 may be formed between the first component 232 and the second component 242 using the wire bond capillary 250. As shown in FIG. 2D-8, the wire bond 260 may be formed between the first component 232 and the second component 242 via the fourth stud bump 233 and a fifth stud bump 243. In some embodiments, the wire bond 260 may be formed between the first component 232 and the second component 242 via the fourth stud bump 233, as shown in FIG. 2D-9. In some embodiments, the wire bond 260 may be formed between the first component 232 and the second component 242 via the fifth stud bump 243, as shown in FIG. 2D-10.

In one or more embodiments, the forming of the wire bond between the first component 232 and the second component 242 may occur without an obstruction caused by one or more adjacent components (not shown) interfering with movement of the wire bond capillary 250 during the forming of the wire bond. In one or more embodiments, the one or more adjacent components causing the obstruction comprises a wall or an edge (not shown) that interferes with a wire bonding process using the wire bond capillary 250.

In such embodiments, the first/edge stud bump 212 has enough wire bonding material such that the first/edge stud bump 212 has a larger height measured from the surface of the substrate 205 compared to a height of the first component 232 or the second component 242 measured from the surface of the substrate 205. In some embodiments, the first/edge stud bump 212 comprises a greater amount wire bonding material than another stud bump (e.g., the second stud bump 214) of the set of stud bumps 210. In other words, the first stud bump 212 has enough wire bonding material or taller enough such that the wire bond capillary 250 can make contact with the first/edge stud bump 212 for forming the wire bond. The wire bond may not be formed if the first stud bump 212 has a height that is not higher than the height of the first component 232 or the second component 242 measured from the surface of the substrate 205, where the first component 232 or the second component 242 may interfere or obstruct the wire bond capillary 250 from making physical contact with the first/edge stud bump 212. Similarly, the second stud bump 214 shall have a height not to exceed the height of the first component 232 (with or without the first binding material 234) or the second component 242 (with or without the second binding material 244) measured from the surface of the substrate 205; otherwise, an inadvertent wire bond may form from the wire bond capillary 250 contacting the second stud bump 214.

In one or more embodiments, a microelectronic assembly may be produced in accordance with the process flow 200 described above.

The various variations of the wire bonds 160 and/or 260 may be described as stitch-to-stitch, ball-stitch-on-ball, or normal ball bonding, where a normal ball bond may be considered to include three basic elements, such as, a ball formation on one end, a terminal stitch on the other end, and the wire material in between the two ends. A stud bump, such as those described herein, is the ball portion of the normal ball bond, whereby the stitch end of the wire bond can be placed on another ball on the component, placed directly to the component itself, a previously completed stitch, or to a stud bump, as described herein.

FIG. 3 illustrates a flowchart for a method S100 for forming a wire bond, according to aspects of the present disclosure. As illustrated in FIG. 3, the method S100 may include, at step S110, placing a set of stud bumps (such as stud bumps 110) on a substrate (such as substrate 105) defining a boundary (such as boundary 120) of a location (such as location 130) for placement of a component (such as component 132), wherein the set of stud bumps comprises a first stud bump (such as first stud bump 112) and a second stud bump (such as second stud bump 114), the first stud bump comprising a greater amount of wire bonding material than the second stud bump; at step S120, placing the component at the location on the substrate via a layer of a binding material (such as binding material 134); and at step S130, forming a wire bond between the component and the first stud bump.

In one or more embodiments of the method S100, the greater amount of wire bonding material in the first stud bump constitutes a volumetric shape of an extra stud bump disposed atop a stud bump similar in size to the second stud bump. In one or more embodiments, the first stud bump having the greater amount of wire bonding material forms a stud bump with a larger height measured from a surface of the substrate compared to a height of the second stud bump measured from the surface of the substrate. In one or more embodiments, the first stud bump can have at least about 10%, at least about 20%, at least about 30%, at least about 40%, at least about 50%, at least about 60%, at least about 70%, at least about 80%, at least about 90%, at least about 100%, at least about 120%, at least about 140%, at least about 160%, at least about 180%, at least about 200%, at least about 250%, at least about 300%, at least about 350%, at least about 400%, at least about 450%, or at least about 500% more wire bonding material than the second stud bump. In one or more embodiments, the second stud bump includes a single stud bump and the first stud bump can have two, three, four, or five stud bumps. In one or more embodiments, the first stud bump can have two, three, four, or five times as many stud bumps as the second stud bump.

In one or more embodiments of the method S100, the forming of the wire bond between the component and the first stud bump is facilitated by a wire bond capillary. In one or more embodiments, the forming of the wire bond between the component and the first stud bump occurs without an obstruction caused by one or more adjacent components interfering with movement of the wire bond capillary during the forming of the wire bond. In one or more embodiments, the one or more adjacent components causing the obstruction comprises a wall or an edge that interferes with a wire bonding process using the wire bond capillary. In one or more embodiments, the binding material may include solder, such as a gold tin alloy solder, lead solder, a thermoset or thermoplastic material, such as epoxy, or any pressure sensitive adhesive materials. In one or more embodiments, the binding material may include any material suitable for eutectic bonding.

In one or more embodiments, a microelectronic assembly is produced in accordance with the method S100 as described above.

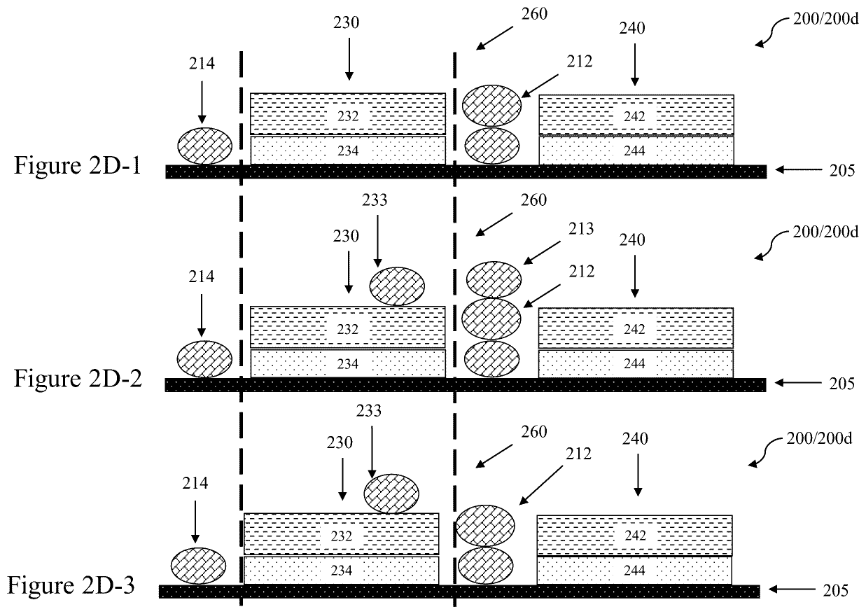

FIG. 4 illustrates a flowchart for a method S200 for forming a wire bond, according to aspects of the present disclosure. As illustrated in FIG. 4, the method S200 may include, at step S210, placing a set of stud bumps (such as stud bumps 210) on a substrate (such as substrate 205) defining a boundary (such as boundary 220) of a first location (such as first location 230) for placement of a first component (such as first component 232); at step S220, placing the first component in the first location on the substrate via a layer of a first binding material (such as first binding material 234); at step S230, placing a second component (such as second component 242) at a second location (such as second location 240) on the substrate via a layer of a second binding material (such as second binding material 244), the second location being adjacent to an edge stud bump (such as first/edge stud bump 212) of the set of stud bumps and outside of the boundary of the first location; and at step S240, forming a wire bond between the first component and the second component, wherein the edge stud bump comprises a greater amount wire bonding material than another stud bump of the set of stud bumps.

In one or more embodiments of the method S200, the greater amount of wire bonding material in the first stud bump constitutes a volumetric shape of an extra stud bump disposed atop a stud bump similar in size to the second stud bump. In one or more embodiments, the first stud bump having the greater amount of wire bonding material forms a stud bump with a larger height measured from a surface of the substrate compared to a height of the second stud bump measured from the surface of the substrate. In one or more embodiments, the first stud bump can have at least about 10%, at least about 20%, at least about 30%, at least about 40%, at least about 50%, at least about 60%, at least about 70%, at least about 80%, at least about 90%, at least about 100%, at least about 120%, at least about 140%, at least about 160%, at least about 180%, at least about 200%, at least about 250%, at least about 300%, at least about 350%, at least about 400%, at least about 450%, or at least about 500% more wire bonding material than the second stud bump. In one or more embodiments, the second stud bump includes a single stud bump and the first stud bump can have two, three, four, or five stud bumps. In one or more embodiments, the first stud bump can have two, three, four, or five times as many stud bumps as the second stud bump.

In one or more embodiments of the method S200, the forming of the wire bond between the first component and the second component is facilitated by a wire bond capillary. In one or more embodiments, the forming of the wire bond between the first component and the second component occurs without an obstruction caused by the first component and the second component, or one or more adjacent components, interfering with movement of the wire bond capillary during the forming of the wire bond. In one or more embodiments, the one or more adjacent components causing the obstruction comprises a wall or an edge that interferes with a wire bonding process using the wire bond capillary.

In one or more embodiments, the wire bond is formed by using the edge stud bump having a thickness larger than a thickness of either or both of a combined thickness of the first component and the layer of the first binding material and/or a combined thickness of the second component and the layer of the second binding material. In one or more embodiments, the first and/or second binding material may include solder, such as a gold tin alloy solder, lead solder, a thermoset or thermoplastic material, such as epoxy, or any pressure sensitive adhesive materials. In one or more embodiments, the binding material may include any material suitable for eutectic bonding.

In one or more embodiments, a microelectronic assembly is produced in accordance with the method S200 as described above.

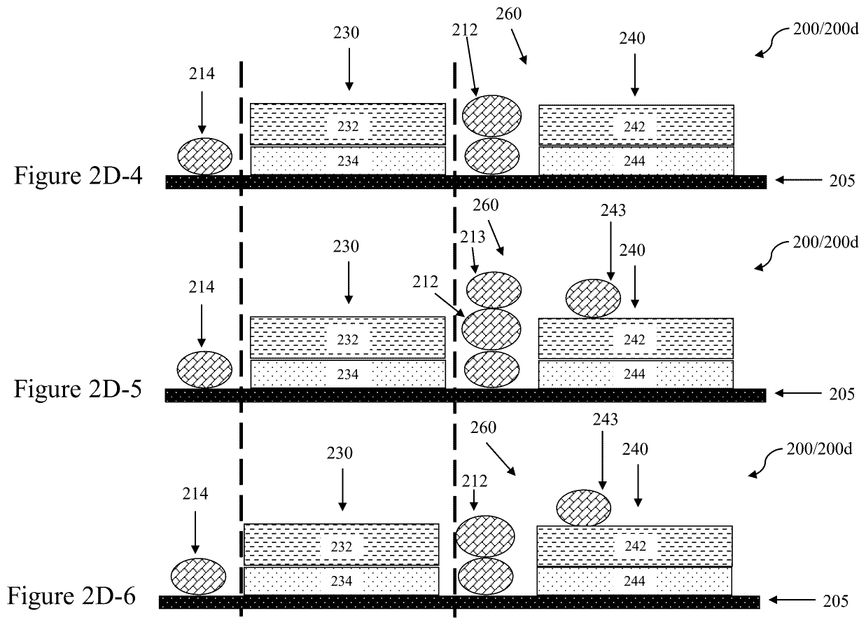

FIG. 5 illustrates a microelectronic assembly 510 comprising a wire bond 500, according to aspects of the present disclosure. In some implementations, the microelectronic assembly 510 may be any component that includes a circuit used in an electronic device, such as for example, but not limited to, a computer, a cellular device, a satellite communication device, a wi-fi device, a radar, a global position system device, or any electronic device.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A method, comprising:
placing a set of stud bumps on a substrate defining a boundary of a location for placement of a component, wherein the set of stud bumps comprises a first stud bump and a second stud bump, the first stud bump comprising a greater amount of wire bonding material than the second stud bump;
placing the component at the location on the substrate via a layer of a binding material; and
forming a wire bond between the component and the first stud bump.

2. The method of claim 1, wherein the greater amount of wire bonding material in the first stud bump constitutes a volumetric shape of an extra stud bump disposed atop a stud bump similar in size to the second stud bump.

3. The method of claim 1, wherein the first stud bump having the greater amount of wire bonding material forms a stud bump with a larger height measured from a surface of the substrate compared to a height of the second stud bump measured from the surface of the substrate.

4. The method of claim 1, wherein the forming of the wire bond between the component and the first stud bump is facilitated by a wire bond capillary.

5. The method of claim 4, wherein the forming of the wire bond between the component and the first stud bump occurs without an obstruction caused by one or more adjacent components interfering with movement of the wire bond capillary during the forming of the wire bond.

6. The method of claim 5, wherein the one or more adjacent components causing the obstruction comprises a wall or an edge that interferes with a wire bonding process using the wire bond capillary.

7. The method of claim 1, wherein the binding material comprises solder including a gold tin alloy, an epoxy or any pressure sensitive adhesive materials, or any material suitable for eutectic bonding.

8. A method, comprising:
placing a set of stud bumps on a substrate defining a boundary of a first location for placement of a first component;
placing the first component in the first location on the substrate via a layer of a first binding material;
placing a second component at a second location on the substrate via a layer of a second binding material, the second location being adjacent to an edge stud bump of the set of stud bumps and outside of the boundary of the first location; and
forming a wire bond between the first component and the second component, wherein the edge stud bump comprises a greater amount wire bonding material than another stud bump of the set of stud bumps.

9. The method of claim 8, wherein the greater amount of wire bonding material in the edge stud bump constitutes a volumetric shape of an extra stud bump disposed atop a stud bump similar in size to the another stud bump of the set of stud bumps.

10. The method of claim 8, wherein the edge stud bump having the greater amount of wire bonding material forms a stud bump with a larger height measured from a surface of the substrate compared to a height of the another stud bump of the set of stud bumps measured from the surface of the substrate.

11. The method of claim 8, wherein the forming of the wire bond between the first component and the second component is facilitated by a wire bond capillary.

12. The method of claim 11, wherein the forming of the wire bond between the first component and the second component occurs without an obstruction caused by the first component and the second component, or one or more adjacent components, interfering with movement of the wire bond capillary during the forming of the wire bond.

13. The method of claim 12, wherein the one or more adjacent components causing the obstruction comprises a wall or an edge that interferes with a wire bonding process using the wire bond capillary.

14. The method of claim 8, wherein the wire bond is formed by using the edge stud bump having a thickness larger than a thickness of either or both of a combined thickness of the first component and the layer of the first binding material and/or a combined thickness of the second component and the layer of the second binding material.

15. The method of claim 8, wherein the first binding material comprises solder including a gold tin alloy.

16. The method of claim 8, wherein the second binding material comprises epoxy or any pressure sensitive adhesive materials.

17. The method of claim 8, wherein the first component is a die and the first binding material is a gold tin solder, and the second component is a printed circuit board and the second binding material is epoxy.

18. A microelectronic assembly produced in accordance with the method of claim 1.

19. A microelectronic assembly produced in accordance with the method of claim 8.

20. A microelectronic assembly, comprising:
a substrate having a set of stud bumps disposed thereon, wherein the set of stud bumps define a boundary of a first location;
a first component disposed at the first location on the substrate via a layer of a first binding material;
a second component disposed at a second location on the substrate via a layer of a second binding material, wherein the second location is adjacent to an edge stud bump of the set of stud bumps and outside of the boundary of the first location; and
a wire bond formed between the first component and the second component, wherein the wire bond is formed from the edge stud bump that comprises a greater amount of wire bonding material than another stud bump of the set of stud bumps.

21. The microelectronic assembly of claim 20, wherein the greater amount of wire bonding material in the edge stud bump constitutes a volumetric shape of an extra stud bump disposed atop a stud bump similar in size to the another stud bump of the set of stud bumps.

22. The microelectronic assembly of claim 20, wherein the edge stud bump having the greater amount of wire bonding material forms a stud bump with a larger height measured from a surface of the substrate compared to a height of the another stud bump of the set of stud bumps measured from the surface of the substrate.

23. The microelectronic assembly of claim 20, wherein the wire bond between the first component and the second component is formed by a wire bond capillary.

24. The microelectronic assembly of claim 23, wherein the wire bond between the first component and the second component is formed without an obstruction caused by the first component and the second component, or one or more adjacent components, interfering with movement of the wire bond capillary during the forming of the wire bond.

25. The microelectronic assembly of claim 24, wherein the one or more adjacent components causing the obstruction comprises a wall or an edge that interferes with a wire bonding process using the wire bond capillary.

26. The microelectronic assembly of claim 20, wherein the wire bond is formed by using the edge stud bump having a thickness larger than a thickness of either or both of a combined thickness of the first component and the layer of the first binding material and/or a combined thickness of the second component and the layer of the second binding material.

27. The microelectronic assembly of claim 20, wherein the first binding material comprises solder including a gold tin alloy.

28. The microelectronic assembly of claim 20, wherein the second binding material comprises epoxy or any pressure sensitive adhesive materials.

29. The microelectronic assembly of claim 20, wherein the first component is a die and the first binding material is a gold tin solder, and the second component is a printed circuit board and the second binding material is epoxy.

30. A microelectronic assembly, comprising:
a substrate having a set of stud bumps disposed thereon, wherein the set of stud bumps comprises a first stud bump and a second stud bump, the first stud bump comprising a greater amount of wire bonding material than the second stud bump;
a component disposed at a location on the substrate via a layer of a binding material, wherein the set of stud bumps define a boundary of the location for the component; and
a wire bond formed between the component and the first stud bump.

31. The microelectronic assembly of claim 30, wherein the greater amount of wire bonding material in the first stud bump constitutes a volumetric shape of an extra stud bump disposed atop a stud bump similar in size to the second stud bump.

32. The microelectronic assembly of claim 30, wherein the first stud bump having the greater amount of wire bonding material forms a stud bump with a larger height measured from a surface of the substrate compared to a height of the second stud bump measured from the surface of the substrate.

33. The microelectronic assembly of claim 30, wherein the wire bond between the component and the first stud bump is formed by a wire bond capillary.

34. The microelectronic assembly of claim 30, wherein the wire bond between the component and the first stud bump is formed without an obstruction caused by one or more adjacent components interfering with movement of the wire bond capillary during the forming of the wire bond.

35. The microelectronic assembly of claim 34, wherein the one or more adjacent components causing the obstruction comprises a wall or an edge that interferes with a wire bonding process using the wire bond capillary.

36. The microelectronic assembly of claim 30, wherein the binding material comprises solder including a gold tin alloy, an epoxy or any pressure sensitive adhesive materials, or any material suitable for eutectic bonding.
